(19) United States
(12) Patent Application Publication
(10) Pub. No.: US 2013/0049870 A1
(43) Pub. Date: Feb. 28, 2013

(54) POWER AMPLIFIER SYSTEM

(71) Applicants: Jun Kyung NA, Gyeonggi-do (KR); Sang Hoon Ha, Gyeonggi-do (KR); Shinichi Iizuka, Gyeonggi-do (KR); Youn Suk Kim, Gyeonggi-do (KR)

(72) Inventors: Jun Kyung NA, Gyeonggi-do (KR); Sang Hoon Ha, Gyeonggi-do (KR); Shinichi Iizuka, Gyeonggi-do (KR); Youn Suk Kim, Gyeonggi-do (KR)

(73) Assignee: Samsung Electro-Mechanics Co., Ltd., Suwon (KR)

(21) Appl. No.: 13/569,519

(22) Filed: Aug. 8, 2012

(30) Foreign Application Priority Data
Aug. 31, 2011 (KR) 10-2011-0088075

(51) Int. Cl. H03F 3/04

(52) U.S. Cl. 330/296

(57) ABSTRACT

Disclosed herein is a power amplifier system, including: a power amplifier; a first regulator generating driving voltage Vd and driving current Id corresponding to preset first reference voltage; a current controller controlling the driving current Id of the first regulator corresponding to applied control voltage; a first resistor connected between the first regulator and the current controller and a second resistor connected between the first regulator and the power amplifier, a bias controller detecting current and voltage corresponding to the driving current and controlling bias current of the power amplifier according to the detected voltage; and a second regulator generating power supply voltage corresponding to preset second reference voltage, whereby characteristics of the power amplifier can be improved by constantly controlling current supplied to the power amplifier even though the input voltage applied to the power amplifier system is increased.

### CROSS REFERENCE(S) TO RELATED APPLICATIONS

This application claims the benefit under 35 U.S.C. Section 119 of Korean Patent Application Serial No. 10-2011-0088075, entitled “Power Amplifier System” filed on Aug. 31, 2011, which is hereby incorporated by reference in its entirety into this application.

### BACKGROUND OF THE INVENTION

1. Technical Field

The present invention relates to a power amplifier system, and more particularly, to a power amplifier system capable of stably supplying current to a power amplifier.

2. Description of the Related Art

Generally, a wireless communication system such as mobile communication terminals, a power amplifier has been used to wirelessly transmit and receive signals. Herein, the power amplifier means an apparatus that effectively amplifies fine signals without being possibly distorted and supplies the amplified signals to loads through an antenna.

The power amplifier includes a CMOS power amplifier designed by a general-purpose CMOS process in a special semiconductor, that is, GaAs process. In this case, the above-mentioned CMOS power amplifier can be mass-produced, such that the power amplifier can be manufactured at a low cost and can perform various functions.

Meanwhile, in order to stably control an operation of the power amplifier, a power controller for the power amplifier has been developed. A technology for more stably supplying power to the power amplifier using the power controller has been researched and developed.

The power amplifier system using the power controller according to the related art includes a voltage controller providing predetermined voltage corresponding to reference voltage to the power amplifier, a current controller controlling driving current according to input control voltage, and a bias controller controlling bias current applied to the power amplifier using driving voltage and driving current, whereby current is stably supplied to the power amplifier by appropriately controlling bias current according to the input control voltage.

However, the bias current applied to the power amplifier is also fluctuated in response to the fluctuation of the applied input voltage. In this case, when a magnitude in the bias current applied to the power amplifier deviates from a predetermined range, the bias controller does not appropriately control the bias current, which leads to deterioration in characteristics of the power amplifier.

### SUMMARY OF THE INVENTION

An object of the present invention is to provide a power amplifier system capable of improving characteristics of a power amplifier by appropriately controlling current supplied to the power amplifier even thought applied input voltage is increased.

According to an exemplary embodiment of the present invention, there is provided a power amplifier system including: a power amplifier; a first regulator generating driving voltage and driving current corresponding to preset first reference voltage; a current controller performing a control so as to supply control current corresponding to applied control voltage; a bias controller detecting current and voltage corresponding to the driving current and controlling bias current of the power amplifier according to the detected voltage; and a second regulator generating power supply voltage corresponding to preset second reference voltage.

The power amplifier system may further include: a first resistor connected between the first regulator and the current controller and a second resistor connected between the first regulator and the power amplifier.

The first regulator may include: a first transistor configured of a source connected to a power supply end, a gate, and a drain connected to a power supply node of the power amplifier; and a first error amplifier including a first input end receiving the first reference voltage, a second input end connected to the drain of the first transistor through a third resistor and connected to a ground through a fourth resistor, and an output end connected to the gate of the first transistor M1.

The current controller may include: a second transistor configured of a source, a gate, and a drain of the first regulator; a fifth resistor connected between the drain of the second transistor and the ground; and a second error amplifier having a first input end receiving the control voltage, a second input end receiving voltage corresponding to current flowing to the drain of the second transistor and to the fifth resistor from the second transistor, and an output end connected to the gate of the second transistor.

The bias controller may include: a third error amplifier having a first input end receiving voltage corresponding to current flowing to the current controller from the first regulator, a second input end receiving the voltage corresponding to the current flowing to the power amplifier from the first regulator, and an output end; a third transistor configured of a gate connected to the output end of the third error amplifier, a drain connected to a power supply end, and a source; and a fourth transistor connected to the third transistor in a cascade type through a sixth resistor connected to the source of the third transistor.

### BRIEF DESCRIPTION OF THE DRAWINGS

FIG. 1 is an overall block diagram of a power amplifier system according to an exemplary embodiment of the present invention.

FIG. 2 is a graph showing power supply voltage Vdd and node N3 voltage according to input voltage Vbat when a second regulator is not connected.

FIG. 3 is a graph showing the power supply voltage Vdd and the node N3 voltage according to the input voltage Vbat when the second regulator is connected.

FIG. 4 is a graph showing a change in driving current Id according to the input voltage Vbat when the second regulator is connected and when the second regulator is not connected.

### DESCRIPTION OF THE PREFERRED EMBODIMENTS

Hereinafter, exemplary embodiments will be described in detail with reference to the accompanying drawings. Prior to this, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

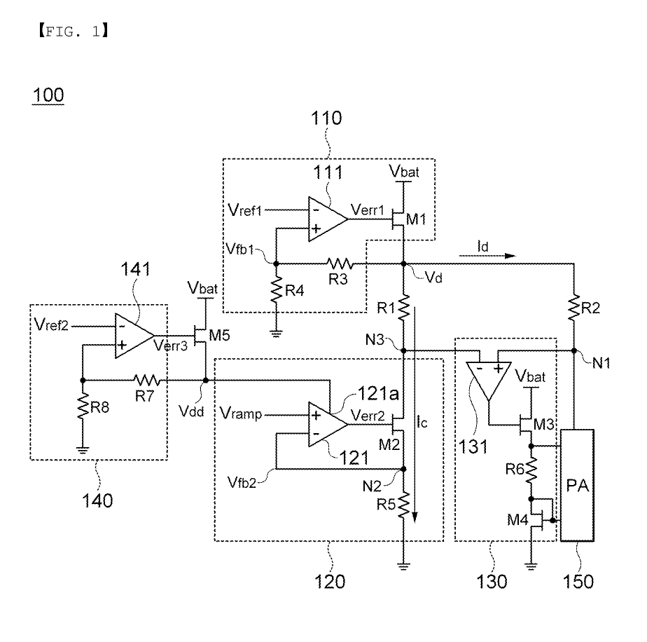

FIG. 1 is an overall block diagram of a power amplifier system according to an exemplary embodiment of the present invention.

Referring to FIG. 1, a power amplifier system 100 according to the exemplary embodiment of the present invention may include an amplifier.

The power amplifier system 100 may include a first regulator 110 generating driving voltage Vd and driving current Id corresponding to preset first reference voltage.

The power amplifier system 100 may include a current controller 120 that performs a control so as to supply control current Ic corresponding to applied control voltage Vramp.

The power amplifier system 100 may include a first resistor R1 connected between the first regulator 110 and the current controller 120 and a second resistor R2 connected between the first regulator 110 and the a power amplifier 150.

The power amplifier system 100 may include a bias controller 130 that detects current and voltage corresponding to the driving current Id and controls bias current from the power amplifier 150 according to the detected voltage.

The power amplifier system 100 may include a second regulator generating power supply voltage corresponding to preset second reference voltage.

Referring to FIG. 1, the first regulator 110 may include a first transistor M1 that is configured of a source connected to a power supply end, a gate, and a drain connected a power node of the power amplifier 150.

Further, the first regulator 110 may include a first error amplifier 111 that has a first input end receiving the first reference voltage, a second input end connected to the drain of the first transistor M1 through a third resistor R3 and connected to a ground through a fourth resistor R4, and an output end connected to the gate of the first transistor M1.

Referring to FIG. 1, the current controller 120 may include a second transistor M2 configured of a source, a gate, and a drain, which is connected to the first regulator 110.

Further, the current controller 120 may include a fifth resistor R5 connected between the drain of the second transistor M2 and a ground.

In addition, the current controller 120 may include a second error amplifier 121 that has a first input end receiving the control voltage Vramp, a second input end receiving voltage corresponding to current flowing in the drain of the second transistor M2 and to the fifth resistor R5 from the second transistor M2, and an output end connected to the gate of the second transistor M2.

Referring to FIG. 1, the bias controller 130 may include a third error amplifier 131 that has a first input end receiving voltage corresponding to current flowing from the first regulator 110 to the current controller 120, a second input end receiving voltage corresponding to current flowing from the first regulator 110 to the power amplifier 150, and an output end.

In addition, the bias controller 130 may include a third transistor M3 that is configured of a gate connected to the output end of the third error amplifier 131, a drain connected to the power supply end, and a source.

Further, the bias controller 130 may include a fourth transistor M4 connected to the fourth transistor M4 in a cascade type through a sixth resistor R6 connected to the source of the third transistor M3.

Referring to FIG. 1, the second regulator 140 may include a fifth transistor M5 that is configured of a source connected to a power supply end, a gate, and a drain connected to the current controller 120.

Further, the second regulator 140 may include a fourth error amplifier 141 that has a first input end receiving the second reference voltage, a second input end connected to the drain of the fifth transistor M1 through a seventh resistor R7 and connected to the ground through an eighth resistor R8, and an output end connected to the gate of the fifth transistor M5.

Hereinafter, an operation process and an effect of the power amplifier system 100 according to the exemplary embodiment of the present invention will be described with reference to the accompanying drawings.

The power amplifier 150 amplifies the input signal applied from the input end (not shown) and outputs the output signal through the output end (not shown). In this case, the operation of the power amplifier 150 is controlled by the driving voltage Vd and the driving current Id, wherein the driving voltage Vd and the driving current Id may be performed by the following control operation.

First, the first regulator 110 of the power amplifier system 100 receives the input voltage Vbat from the power supply end connected to the source terminal of the first transistor M1 and generates the driving voltage Vd and the driving current Id corresponding to a preset first reference voltage Vref1.

The first error amplifier 111 compares the preset first reference voltage Vref1 with feedback voltage Vfb1 divided by the first resistor R1 and the second resistor R2 and outputs the compared results to the gate terminal of the first transistor M1 as an error value Verr1.

To this end, the first error amplifier 111 may be configured to include an inverting terminal (−) to which the preset first reference voltage Vref1 is supplied, a non-inverting terminal (+) to which the feedback voltage Vfb1 is supplied, and an output terminal connected to the gate terminal of the first transistor M1.

Herein, the first reference voltage Vref1 may be generated from a band gap reference generator (BGR) (not shown). The BGR generates the first reference voltage Vref1 having a predetermined level that is not affected by temperature, supply voltage, and process parameters, or the like. The structure and operation of the BGR is general matters and therefore, the detailed description thereof will be omitted.

The first transistor M1 passes the input voltage Vbat to the driving voltage Vd in response to the error value Verr1 output from the error amplifier. To this end, the first transistor M1 may be implemented as a PMOS transistor and the first transistor M1 may be configured of the source connected to the power supply end, the gate, and the drain connected to the power node N1 of the power amplifier 150 through the second resistor R2. Here, the type of the first transistor M1 is not limited to the PMOS transistor and therefore, various types of transistors may be used.

Describing in more detail the operation process of the first regulator 110, when the first reference voltage Vref1 is higher than the feedback voltage Vfb1 divided by the third resistor R3 and the fourth resistor R4, the output voltage Verr1 of the first error amplifier 111 becomes low, while when the first reference voltage Vre1 is lower than the feedback voltage Vfb1, the output voltage Verr1 of the first error amplifier becomes high.

When the output voltage Verr1 of the first error amplifier 111 becomes low, gate-source voltage is increased and on-resistance is reduced in the case in which the first transistor M1 is a P-channel MOS transistor, thereby increasing the driving voltage Vd. On the other hand, when the output voltage Verr1 of the first error amplifier 111 becomes high, the on-resistance of the first transistor M1 is increased and thus, the driving voltage Vd is lowered, thereby generating the driving voltage Vd maintained at a predetermined voltage.

The fifth resistor R5 included in the current controller 120 is connected between a node N2 and a ground GND, such that voltage corresponding to current from the drain terminal of the second transistor M2 to the ground GND via the N2 is detected at the node N2.

Further, the second error amplifier 121 included in the current controller 120 generates a current control signal Verr2 using the control voltage Vramp and feedback voltage Vfb2 applied to the node N2 by the fifth resistor R5. To this end, the second error amplifier 121 may be configured to include a non-inverting terminal (+) to which the control voltage Vramp is supplied, an inverting terminal (−) to which the feedback voltage Vfb2 detected at the node N2 is supplied, and an output terminal connected to the gate terminal of the second transistor M2.

Here, the control voltage Vramp may be preset power supply voltage. For example, when the power amplifier system 110 is applied for a transmission system, the control voltage Vramp may be set to be voltage corresponding to transmission power.

The current controller 120 configured as described above, which is operated as a voltage follower having the control voltage Vramp, generates the current control signal Verr2 according to the voltage level of the control voltage Vramp and the feedback voltage Vfb2 and outputs the generated current control signal to the gate terminal of the fifth transistor M5 to control the fifth transistor M5, such that control current Ic flowing via the first resistor R1 and the second transistor M2 can be controlled.

When the control current Ic controlled by the current controller 120 is determined, the driving current Id is determined by a resistance ratio between the first resistor R1 connected between the first regulator 110 and the current controller 120 and the second resistor R2 connected between the first regulator 110 and the power amplifier 150.

For example, the first resistor R1 is set to be 50Ω and the second resistor R2 is 50 mΩ. As a result, the first resistor R1 and the second resistor R2 may be configured to have a resistance ratio of 1000:1. Therefore, the current flowing in the power amplifier 150 via the second resistor R2 may be used as the driving current Id that is provided to the power amplifier 150.

The third error amplifier 131 included in the bias controller 130 detects the voltage applied to the node N3 and receives the detected voltage through the non-inverting terminal (+) and detects the voltage applied to the power node N1 and receives the detected voltage through the inverting terminal (−).

In this case, the third error amplifier 131 provides the difference voltage between two voltages input through the inverting terminal and the non-inverting terminal to the gate voltage of the third transistor M3. Next, the gate voltage is applied to the third transistor M3 and the third transistor M3 is operated according to the gate voltage to determine the current flowing from the source of the fourth transistor M4 to the drain thereof, such that the two voltages received through the inverting terminal and the non-inverting terminal of the third error amplifier 131 are equal to each other by controlling the bias current flowing in the power amplifier 150.

The source terminal of the fifth transistor included in the second regulator 140 is connected to the power supply end to supply the input voltage Vbat and generates the power supply voltage Vdd corresponding to the preset second reference voltage Vref2. Here, the power supply voltage Vdd is the voltage necessary to drive the second transistor M2 included in the current controller 120.

The fourth error amplifier 141 included in the second regulator 140 compares the preset second reference voltage VREF2 with the feedback voltage Vfb2 divided by a seventh resistor R7 and an eighth resistor R8 and outputs the compared results to the gate terminal of the fifth transistor M5 as an error value Verr3.

To this end, the fourth error amplifier 141 may be configured to include the inverting terminal (−) supplied with the preset second reference voltage Vref2, the non-inverting terminal (+) supplied with the feedback voltage Vfb2, and the output terminal connected to the gate terminal of the fifth transistor M5.

Here, the second reference voltage VREF2 may be generated from the band gap reference generator (BGR) (not shown).

The fifth transistor M5 passes the input voltage Vbat to the power supply voltage Vdd of the second transistor M2 in response to the error value Verr3 output from the error amplifier. To this end, the fifth transistor M5 may be implemented as the PMOS transistor and the fifth transistor M5 may be configured of the source connected to the power supply end, the gate, and the drain connected to the current controller 120. In more detail, the drain terminal of the fifth transistor M5 may be connected to a power supply terminal 121a of the second transistor M2 included in the current controller 120. The type of the fifth transistor M5 is not limited to the PMOS transistor and therefore, various types of transistors may be used.

Describing in more detail the operation process of the second regulator 140, when the second reference voltage Vref2 is higher than the feedback voltage Vfb2 divided by the seventh resistor R7 and the eighth resistor R8, the output voltage Verr3 of the fourth error amplifier 141 becomes low, while when the second reference voltage Vref2 is lower than the feedback voltage Vfb2, the output voltage Verr3 of the fourth error amplifier 141 becomes high.

When the output voltage Verr3 of the fourth error amplifier 141 becomes low, the gate-source voltage is increased and the on-resistance is reduced in the case in which the fifth transistor M5 is a P-channel MOS transistor, thereby increasing the power supply voltage Vdd. On the other hand, when the output voltage Verr3 of the fourth error amplifier 141 becomes high, the on-resistance of the fifth transistor M5 is increased and thus, the power supply voltage Vdd is lowered, thereby generating the power supply voltage Vdd at a predetermined voltage.

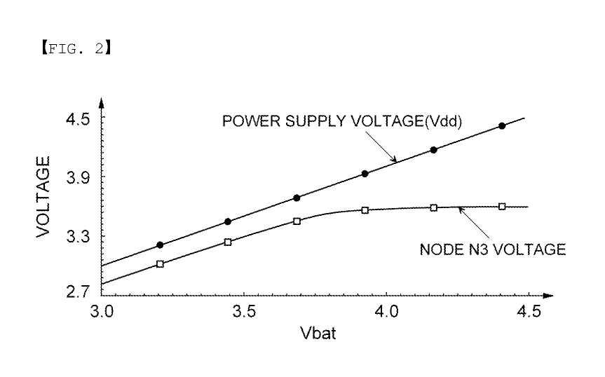

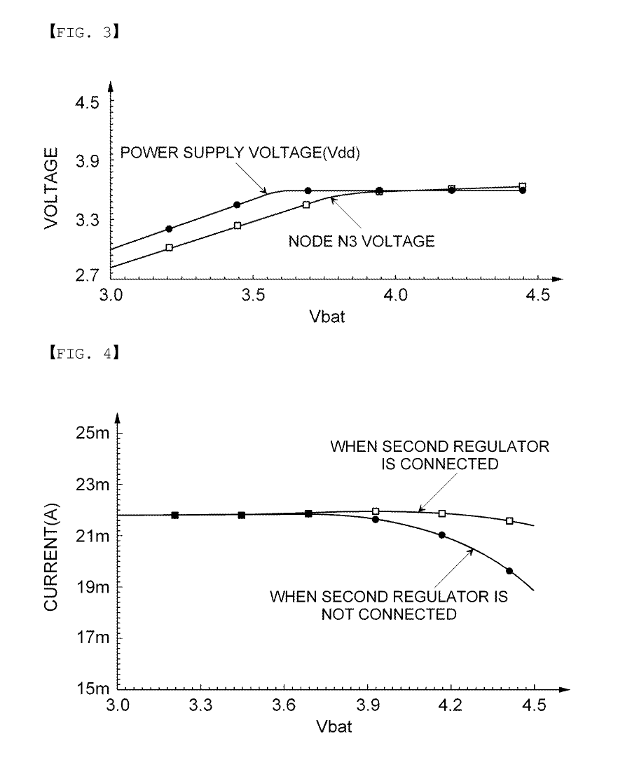

FIG. 2 is a graph showing power supply voltage Vdd and node N3 voltage according to input voltage Vbat when a second regulator is not connected and FIG. 3 is a graph showing the power supply voltage Vdd and the node N3 voltage according to the input voltage Vbat when the second regulator is connected.

Referring to FIG. 2, when the second regulator 140 is not connected, the power supply voltage Vdd driving the second transistor M2 is provided by the input voltage Vbat. Therefore, it can be appreciated that as the input voltage Vbat is increased, the power supply voltage Vdd may be increased accordingly. However, it can be appreciated that the node N3 voltage may be constantly maintained at 3.6 V even though the input voltage Vbat is increased to 3.8V or more according to the operation of the first regulator 110.

Therefore, as shown in FIG. 2, when the input voltage Vbat is increased to 3.8 V or more, the deviation between the power supply voltage Vdd and the node N3 voltage is increased accordingly.

However, referring to FIG. 3, when the second regulator 140 is connected, the power supply voltage Vdd is constantly maintained at 3.6V even though the input voltage Vbat is increased to 3.8V or more according to the operation of the second regulator 140.

Therefore, unlike the case in which the second regulator 140 is not connected, the deviation between the power supply voltage Vdd and the node N3 voltage does not occur even though the input voltage Vbat is increased to 3.8V or more.

FIG. 4 is a graph showing a change in the driving current Id according to the input voltage Vbat when the second regulator 140 is connected and when the second regulator 140 is not connected.

Referring to FIG. 4, when the input voltage Vbat is 3.0V, the driving current Id indicates 21.4 mA when the second regulator 140 is connected and when the second regulator 140 is not connected. However, when the input voltage Vbat is increased to 3.8V or more, as shown in FIG. 2, the driving current Id is gradually reduced by the deviation between the power supply voltage Vdd and the node N3 voltage in the case in which the second regulator 140 is not present. As a result, when the input voltage Vbat is 4.5V, the driving current Id indicates 18.4 mA. On the other hand, when the second regulator 140 is connected, as shown in FIG. 3, the deviation between the power supply voltage Vdd and the node N3 voltage does not occur and thus, the driving current Id is constantly maintained even though the input voltage Vbat is increased to 3.8V or more.

As such, the driving current Id may be constantly maintained independent of the fluctuation of the input voltage Vbat according to the operation of the second regulator 140 and thus, stably control the power amplifier 150, thereby improving the characteristics of the power amplifier 150.

According to the power amplifier system according to the exemplary embodiments of the present invention, the characteristics of the power amplifier can be improved by appropriately controlling the current supplied to the power amplifier even though the applied input voltage is increased.

As a result, the efficiency of the power amplifier system can be increased.

The configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

What is claimed is:

1. A power amplifier system, comprising:
a power amplifier;
a first regulator generating driving voltage and driving current corresponding to preset first reference voltage;
a current controller performing a control so as to supply control current corresponding to applied control voltage;
a bias controller detecting current and voltage corresponding to the driving current and controlling bias current of the power amplifier according to the detected voltage; and
a second regulator generating power supply voltage corresponding to preset second reference voltage.

2. The power amplifier system according to claim 1, further comprising: a first resistor connected between the first regulator and the current controller and a second resistor connected between the first regulator and the power amplifier.

3. The power amplifier system according to claim 1, wherein the first regulator includes:
a first transistor configured of a source connected to a power supply end, a gate, and a drain connected to a power supply node of the power amplifier; and
a first error amplifier including a first input end receiving the first reference voltage, a second input end connected to the drain of the first transistor through a third resistor and connected to a ground through a fourth resistor, and an output end connected to the gate of the first transistor M1.

4. The power amplifier system according to claim 1, wherein the current controller includes:
a second transistor configured of a source, a gate, and a drain of the first regulator;
a fifth resistor connected between the drain of the second transistor and the ground; and
a second error amplifier having a first input end receiving the control voltage, a second input end receiving voltage corresponding to current flowing to the drain of the second transistor and to the fifth resistor from the second transistor, and an output end connected to the gate of the second transistor.

5. The power amplifier system according to claim 1, wherein the bias controller includes:
a third error amplifier having a first input end receiving voltage corresponding to current flowing to the current controller from the first regulator, a second input end receiving the voltage corresponding to the current flowing to the power amplifier from the first regulator, and an output end;
a third transistor configured of a gate connected to the output end of the third error amplifier, a drain connected to a power supply end, and a source; and
a fourth transistor connected to the third transistor in a cascade type through a sixth resistor connected to the source of the third transistor.

6. The power amplifier system according to claim 1, wherein the second regulator includes:
a fifth transistor configured of a source connected to a power supply end, a gate, and a drain connected to the current controller; and
a fourth error amplifier having a first input end receiving the second reference voltage, a second input end connected to the drain of the fifth transistor through a seventh resistor and connected to the ground through an eighth resistor, and an output end connected to the gate of the fifth transistor.
